(19) United States
(12) Patent Application Publication
(10) Pub. No.: US 2018/0248104 A1
(43) Pub. Date: Aug. 30, 2018

(54) METHOD FOR CONTROLLING THE MOVEMENT OF AN ABRIKOSOV VORTEX

(71) Applicants: CENTRE NATIONAL DE LA RECHERCHE SCIENTIFIQUE - CNRS, Paris (FR); UNIVERSITE DE BORDEAUX, Bordeaux (FR)

(72) Inventors: Alexandre Bouzdine, Gradignan (FR); Brahim Lounis, Pessac (FR); Philippe Tamarat, Cursan (FR)

(73) Assignees: CENTRE NATIONAL DE LA RECHERCHE SCIENTIFIQUE - CNRS, Paris (FR); UNIVERSITE DE BORDEAUX, Paris (FR)

(21) Appl. No.: 15/754,346

(22) PCT Filed: Aug. 23, 2016
(86) PCT No.: PCT/FR2016/052105

§ 371 Date: Feb. 22, 2018

(30) Foreign Application Priority Data
Aug. 28, 2015 (FR) 15 58027

(51) Int. Cl. H01L 39/14; H01L 39/22

(52) U.S. Cl. CPC H01L 39/148; H01L 39/223

(57) ABSTRACT

The invention relates to a method for controlling the movement of an Abrikosov vortex of an element consisting of a supraconductive material, a so-called supraconductive element, comprising a step of inhomogeneously heating the supraconductive element with the Abrikosov vortex in a heating zone in such a way as to move the Abrikosov vortex towards the heating zone.

The invention relates to a method for controlling the movement of an Abrikosov vortex of an element composed of a superconducting material, referred to as a superconductor.

It is known that a type-II superconductor allows penetration of a magnetic field of a value between a first critical field and a second critical field, in the form of an Abrikosov vortex.

An Abrikosov vortex is a magnetic flux tube around which a current flows.

A superconductor has specific physical properties, particularly when part of a Josephson junction.

A Josephson junction is formed for example by a three-layer stack of two thin layers of the superconductor separated by a weak link.

The weak link consists in particular of a thin layer of an insulating material or of a metal.

In such a Josephson junction, a current exists without any potential difference being applied, due to the tunneling of Cooper pairs of spins of superconducting electrons through the barrier formed by the weak link.

The maximum current that can pass through the junction is called the critical current.

Josephson junctions have enabled significant technological advances, such as the development of SQUID magnetometers.

Another important application of Josephson junctions is information storage and it also allows generating a quantum bit, or qubit.

It has been shown that the critical current of a Josephson junction is heavily influenced by the presence of vortices in its immediate vicinity, and in particular can be, greatly reduced by the distribution of vortices in the superconducting layers of the Josephson junction.

To overcome this difficulty, it is known to alter the overall distribution of vortices in the superconducting layers, for example via a controlled application of a magnetic field.

However, this general approach does not allow controlling the movement of a single vortex.

The ability to move a single vortex by magnetic force microscopy has recently been demonstrated.

However, this method has the disadvantage of allowing only a slow movement of the vortex, and only at a very small scale.

Another disadvantage lies in the fact that a force applied to the vortex by the microscope is often less than the force trapping the vortex in the superconductor, and then the movement of the vortex by this method is unachievable.

The purpose of the invention is to at least partially overcome these disadvantages.

To this end, the invention relates to a method for controlling the movement of an Abrikosov vortex of an element composed of a superconducting material, referred to as a superconductor, comprising a step of non-uniform heating, in a heating zone, of the superconductor having the Abrikosov vortex in such a way as to move the Abrikosov vortex towards the heating zone.

With the invention, because the heating is not uniform, a temperature gradient, is generated and the vortex is attracted to the hottest zone, which is the heating zone, towards which it is moved.

It is thus sufficient to generate the heating zone at the location where one wishes to position the vortex, to move the vortex in a controlled manner.

According to another feature of the invention, during the step of non-uniform heating of the superconductor, the heating zone is heated by applying a laser beam.

According to another feature of the invention, the method comprises a step of focusing the laser beam on the heating zone.

According to another feature of the invention, during the heating step, the laser beam generates an attraction force on the vortex of value:

$${f}_{T} = - \frac{{Φ}_{0}}{4 π} * \frac{\partial {H}_{c 1}}{\partial T} * \vert ∇ T \vert ,$$

where Φ₀ is a magnetic flux quantum, H_{c1} is a first critical field of the superconductor, and T is a temperature associated with the laser beam.

According to another feature of the invention, the Abrikosov vortex moves towards the heating zone if the attraction force generated by the laser beam is greater than the force trapping the Abrikosov vortex in the superconductor.

According to another feature of the invention, the trapping force is equal to:

Fₚ=j_{c}Φ₀, where Φ₀ is a magnetic flux quantum and j_{c} is a critical current of the superconductor.

According to another feature of the invention, the laser power is between 1 μW and 1000 μW.

According to another feature of the invention, the wavelength of the laser is within the visible electromagnetic spectrum.

According to another feature of the invention, the method comprises a step of determining the value of the trapping force by means of the minimum force to be applied by the laser beam such that the Abrikosov vortex is moved.

The invention also relates to use of the control method as described above to form a distribution of vortices in a superconductor, wherein the method as described above is applied to at least one of the vortices of an initial distribution of vortices.

Preferably, the method as described above is successively applied to each vortex of the distribution of vortices.

Advantageously, a step is provided for avoiding collisions between the vortex moved by the method as described above and the other vortices of the distribution of vortices.

The invention also relates to a control method as described above in a Josephson junction provided with an Abrikosov vortex, for controlling a value of a critical current of said Josephson junction.

The invention also relates to a use of the method as described above for information storage, wherein information is written by movement of the Abrikosov vortex.

The invention also relates to a computer program comprising a set of instructions implementing the steps of the method as described above when executed by a processor.

The invention also relates to a non-transitory computer-readable storage medium comprising a computer program as described above.

Other features and advantages of the invention will be apparent from reading the following description. This is purely illustrative and is to be read in conjunction with the accompanying drawings in which:

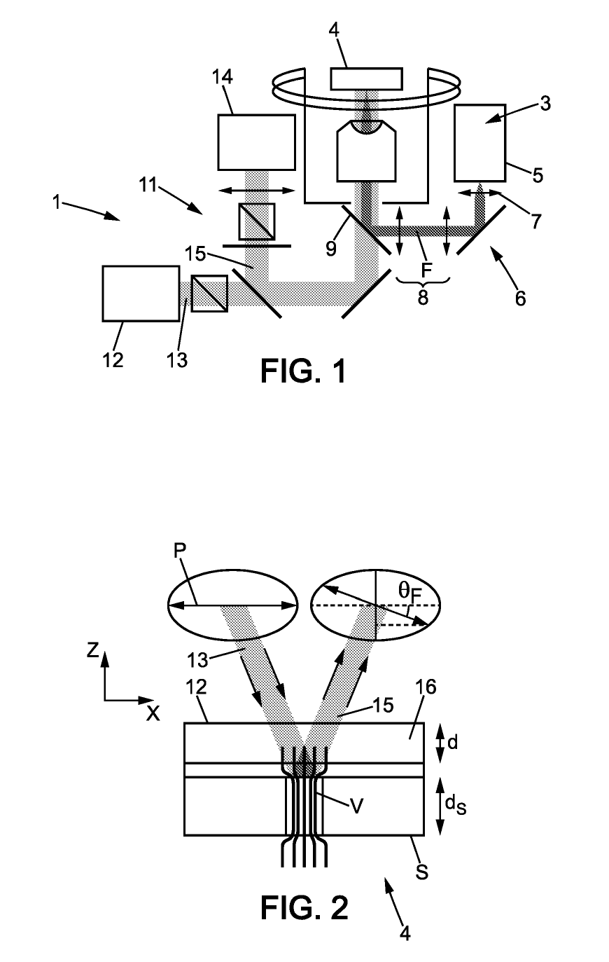

FIG. 1 illustrates a schematic representation of a system for implementing a method for controlling the movement of an Abrikosov vortex according to the invention;

FIG. 2 illustrates a cross-sectional view of a sample of a superconductor for the system of FIG. 1;

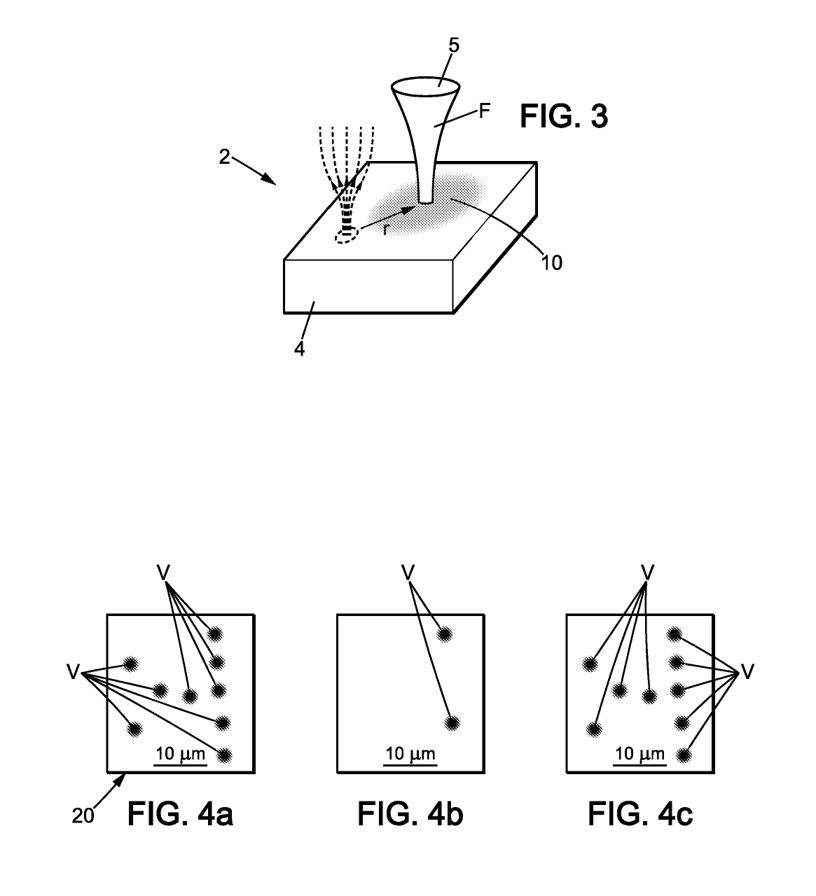

FIG. 3 illustrates a perspective view of the movement of an Abrikosov vortex by means of a laser beam of the system of FIG. 1;

FIGS. 4a, 4b, and 4c illustrate an experimental sequence in moving each vortex of a set of vortices by means of the system of FIG. 1;

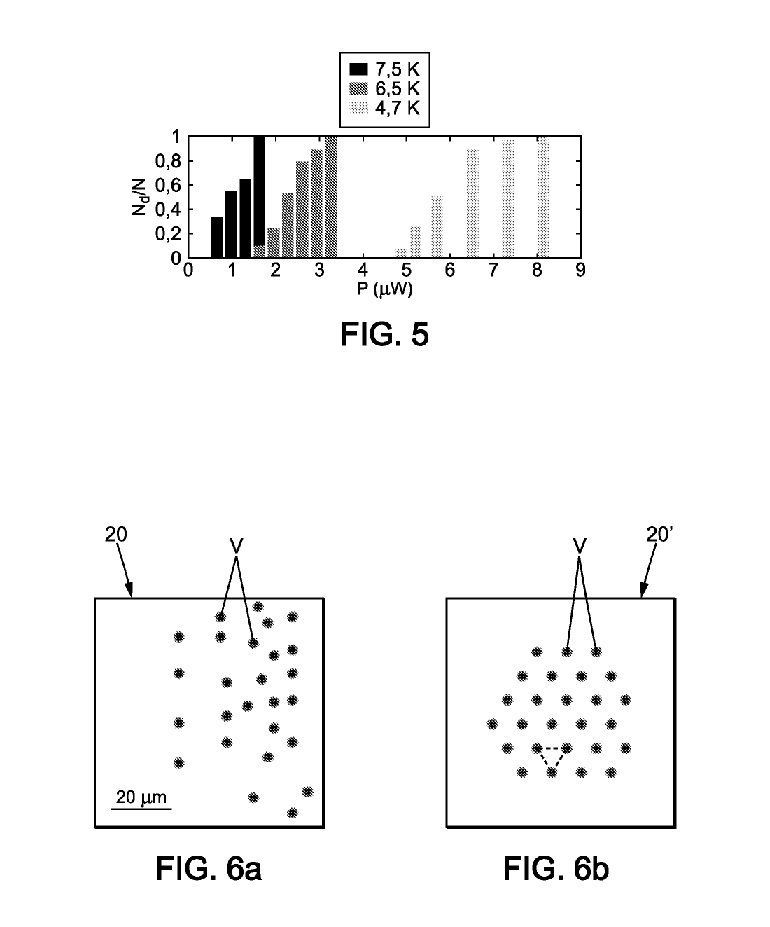

FIG. 5 illustrates a histogram of the ratio of a number (N_{d}) of vortices moved by the laser beam of FIG. 1 among the set of nine vortices (N) of FIGS. 4a, 4b, and 4c, according to the power of the laser beam at three different temperatures, T=7.5 K, T=6.5 K, and T=4.7 K;

FIG. 6a illustrates an initial distribution of vortices in a sample; and

FIG. 6b illustrates a distribution of vortices after movement by the method according to the invention.

### SYSTEM FOR IMPLEMENTING A METHOD FOR CONTROLLING THE MOVEMENT OF AN ABRIKOSOV VORTEX

As can be seen in FIG. 1, a system 1 for implementing a method for controlling the movement 2 of an Abrikosov vortex according to the invention comprises a heat source 3 applied to a sample 4 of a superconductor.

The heat source 3 is configured to heat the sample 4 non-uniformly, as will be detailed below.

In the illustrated embodiment, the heat source 3 for non-uniform heating is a laser 5 capable of emitting a laser beam F.

As can be seen in FIG. 1, the system 1 comprises means 6 for shaping the laser beam comprising a collimation lens 7 of the laser 5 and a telecentric lens 8.

The shaping means further comprise a beam splitter 9.

The shaping means 6 allow focusing the laser beam onto a specific area of the sample 4 called the heating zone 10, as will be explained.

The system 1 also comprises imaging means 11 for visually monitoring the movements of the Abrikosov vortex.

As can be seen in FIG. 1, the imaging means 11, preferably magneto-optical, comprise a source of incident light 12, for example a source of white light, directed onto an outer face of the sample 4.

The incident light 13 emitted by the source of incident light 12 has rectilinear polarization P in a direction called X.

The imaging means 11 also comprise a display element 14, such as a camera CCD, oriented to receive a light beam 15 emitted by the source 12 and reflected by the sample 4, as will be explained.

The system 1 also comprises a cooling device for the sample 4, not shown.

The system 1 also comprises a device for applying a magnetic field to the sample 4, not shown.

Of course, the invention is not limited to the system shown, and other systems can be used for the method 2 according to the invention.

For example, according to one variant, the system is in the form of a wire comprising a microswitch for heating the sample 4 at a sufficient distance from the vortex.

Sample

The sample 4 comprises a thin layer, hereinafter called a film, of the superconductor S.

The superconductor S is type II, meaning that when the temperature applied to the sample 4 by the cooling device is below a superconducting transition temperature, denoted T_{c}, a magnetic field applied by the magnetic field application device penetrates as an Abrikosov vortex if the applied magnetic field is between a first critical magnetic field H_{c1} and a second critical magnetic field H_{c2}.

As already indicated, an Abrikosov vortex is a magnetic flux tube around which a current flows.

Hereinafter, a reference to an Abrikosov vortex uses the term vortex V.

In the embodiment illustrated in FIG. 2, the superconductor film is a film of niobium (Nb) having a thickness d_{S}.

Advantageously, the film of niobium is deposited on a substrate, for example of SiO₂/Si, not shown.

Preferably, the deposition of niobium on the substrate is carried out by a technique of magnetron sputtering, known to those skilled in the art.

As can be seen in FIG. 2, the sample 4 also comprises a visual indicator layer 16.

The visual indicator layer 16 is configured to change the polarization of the incident light 13, as will be explained, which allows visually monitoring the movement of the vortex V by means of the imaging means 11.

In FIG. 2, the composition of the indicator layer 16 is based on a crystal of Bi:LuIG with in-plane magnetization.

The layer of Bi:LuIG forms an outer face 17 of the sample 4.

The incident light 13 of the magneto-optical imaging means 11 is directed onto the layer of Bi:LuIG 16, where the polarization of the beam is changed due to a Faraday effect from the interaction between the light source and a magnetic field of the vortex V.

Advantageously, the polarization of the beam rotates so that an angle between the polarization of the reflected beam 15 and the polarization of the incident beam 13 is an angle θ_{F}=2ϑB_{Z}d, where ϑ is a Verdet constant of the layer 16 of Bi:LuIG, d is a thickness of the layer 16 of Bi:LuIG, and B_{Z} is a component along an axis Z of the magnetic field of the vortex V.

Method for the Controlled Movement of Each Vortex

The method for controlling the movement of a single vortex V according to the invention comprises a step of non-uniform heating of the superconductor S in the heating zone 10 in such a way as to move the vortex V towards the heating zone 10.

“Single” is understood to mean that the method 2 enables controlling the individual movement of each vortex of a distribution of vortices.

As can, be seen in FIG. 3, the laser beam F is directed onto the sample, which creates the heating zone 10.

The laser is advantageously focused on the heating zone 10.

During the heating step, the laser beam F generates an attraction force on the vortex V of a value:

$${f}_{T} = - \frac{{Φ}_{0}}{4 π} * \frac{\partial {H}_{c 1}}{\partial T} * \vert ∇ T \vert ,$$

where Φ₀ is a magnetic flux quantum, H_{c1} is the first critical field of the superconductor, T is a temperature associated with the laser beam, and ∇T is the temperature gradient generated by the laser beam.

Note that the gradient ∇T generated by the laser beam F is dependent on the distance between the heating zone 10 and the vortex V and on the laser power P according to Fourier's law of heat transfer in the sample 4.

The derivative of the first critical field H_{c1} with the temperature is written as:

$$\frac{\partial {H}_{c 1}}{\partial T} = \frac{{Φ}_{0}}{4 {πλ}_{0}^{2} {T}_{c}} ( lnk + 0.5 )$$

where λ₀ is a magnetic penetration depth into the superconductor film, and κ is a Ginzburg-Landau parameter of the superconductor film.

The trapping force is again expressed as:

$${f}_{T} = {( \frac{{Φ}_{0}}{4 {πλ}_{0}} )}^{2} ( lnk + 0.5 ) \frac{∇ T}{{T}_{c}} .$$

The vortex V moves towards the heating zone 10 if the attraction force generated by the laser beam F is greater than, a force trapping the Abrikosov vortex in the superconductor, exerted by trapping centers.

The trapping force is equal to:

Fₚ=j_{c}Φ₀, where j_{c} is a critical current of the superconductor.

The minimum vortex displacement force f_{T}^{min} is therefore

$${( \frac{∇ T}{{T}_{c}} )}_{min} = \frac{{( 4 π )}^{2}}{( lnk + 0.5 )} \frac{{j}_{c} {λ}_{0}^{2}}{{Φ}_{0}}$$

Note that the critical current depends on the thickness d_{S} of the superconductor S film, which implies that the minimum force is dependent on the thickness of the superconductor film.

Also note that the critical current, and therefore the minimum force, is also dependent on the temperature applied to the sample 4.

One will note that the maximum power of the laser beam is defined by a condition according to which the size of the beam, particularly the radius of the beam, is smaller than the distance between vortices when several vortices V are generated in the superconductor film.

### EXPERIMENTAL RESULTS

### Experiment 1

A first experiment is conducted according to the method 2, implemented by the system 1 on the sample 4.

In this first experiment, the Nb film of the sample 4 has a thickness d_{S} of about 450 nm.

The temperature is lowered by the cooling device to a value of T=4.7 K, below the transition temperature T_{C}=8.4 K.

An external magnetic field Hₑₓₜ is applied with a value of Hₑₓₜ=4.4 Oe.

As can be seen in FIG. 4, an initial distribution 20 of vortices V results from these temperature and magnetic field conditions.

In a known manner, the positions of the vortices V in the sample 4 are a function of the trapping centers of the superconductor S film.

In FIG. 4a, nine vortices V of the initial distribution 20 are illustrated.

In this experiment, the laser 5 has a power P and a radius r₀ of approximately 0.4 μm.

The laser beam F is directed towards the outer face 12 of the sample 4.

The laser beam F preferably extends transversely to a plane of the outer face 12.

The laser beam F is focused on the outer face 12, at a successive distance r=4 μm from each vortex V of the distribution 21 of vortices V.

The laser is of a visible wavelength, of about 630 nm.

The laser beam locally heats the sample 4, which creates the heating zone 11.

The heating by laser lasts for 1 second.

As can be seen in FIG. 4b, for a laser power of 4.9 μW, two vortices V are moved.

As can be seen in FIG. 4c, all the vortices V are moved for a power Pₘᵢₙ of about 7.3 μW.

### Experiment 2

The experimental conditions are unchanged from those of the first experiment.

In particular, the sample 4 is identical to that of the first experiment.

The laser is identical to that of the first experiment.

The laser is focused at a distance r=4 μm from each vortex V of the distribution 21.

The sample 4 is cooled to three temperatures T: T=7.5 K, 6.5 K, and T=4.7 K.

As can be seen in FIG. 5, at T=4.7 K, 100% of the nine vortices V are moved for a laser power greater than or equal to 7.2 μW.

At T=6.5 K, 100% of the nine vortices V are moved for a laser power greater than or equal to 3.3 μW.

At T=7.5 K, 100% of the nine vortices V are moved for a laser power greater than or equal to 1.8 μW.

One will note that the closer the temperature is to the superconducting transition temperature, the lower the minimum power, which is due to the fact that the trapping force increases as the applied temperature decreases.

### Experiment 3

The sample 4 is identical to that of the first experiment.

The laser is identical to that of the second experiment.

The laser is focused at a distance r=1 μm from each vortex V of the distribution 20.

Under these conditions, at T=4.7 K, 100% of the nine vortices. V are moved for a laser power greater than or equal to 6.5 μW.

In this experiment, the measured maximum power is about 15 μW in order not to exceed the superconducting transition temperature.

Modeling based on Fourier's law of heat transfer in the sample 4 enables determining that the temperature gradient ∇T generated by the laser beam F at power Pₘᵢₙ is about 2 K/μm.

As the magnetic penetration depth into the superconductor film, is equal to 90 nm, and the Ginzburg-Landau parameter K is equal to 6, then the trapping force is evaluated, according to the equation, to be about 9 pN/μm.

An independent measurement of the critical current gives a value of j_{c}=0.7·10⁶ A/cm², which corresponds to a trapping force of about 14 pN/μm.

One can see that both methods give a value for the trapping force of the same order of magnitude, which ensures that the method 2 allows determining the value of the critical current.

### Computer Program

The invention also relates to a computer program comprising a set of instructions implementing the steps of the method 2 when executed by a processor.

The invention also relates to a non-transitory computer-readable storage medium comprising a computer program as described above.

### Experiment 4

FIG. 6a illustrates another initial distribution 20 of vortices V, created in the sample 4 under an external field of approximately 4.3 Oe.

As can be seen in FIG. 6b, the computer program based on the method 2 allows rearranging the initial distribution 20 into a desired distribution 20′ that is triangular.

Preferably, the method also comprises a step for avoiding collisions between the vortex moved by the method 2 and the other vortices of the sc distribution of vortices 20.

Numerical Estimation

This numerical estimation is based on Fourier's law, using software from COMSOL Multiphysics (trademark).

The Nb film of the sample 4 has a thickness d_{S} of approximately 5 nm.

The laser 5 has a power P=530 μW.

The vortex is moved over a distance of 300 nm with a time constant of 10 ps.

This estimation demonstrates that the method 2 of the invention allows moving a vortex at a frequency of about 100 GHz, which is a much higher value than the movement frequencies known from the prior art.

Such a movement frequency enables using the method 2 for information storage.

Uses

The method 2 is particularly applicable to a Josephson junction provided with an Abrikosov vortex for controlling a value of the critical current of the Josephson junction.

As already indicated, a Josephson junction is multilayer, preferably a three-layer stack of two thin layers of the superconductor separated by a weak link.

The weak link consists in particular of a thin layer of an insulating material or a metal.

In such a Josephson junction, a current exists without any potential difference being applied, due to the tunneling of Cooper pairs of spins of superconducting electrons through the barrier formed by the weak link.

One will recall that the critical current is the maximum current that can pass through the Josephson junction.

With the method 2, it is possible to change the value of the critical current by moving the vortex, due to the fact that the critical current of the Josephson junction is heavily influenced by the presence of vortices in its immediate vicinity.

The method according to the invention allows controlling the movement of each vortex of a set of vortices in a fast and reliable manner, and is advantageously applicable to the uses described above (distribution of vortices, information storage, Josephson junction).

1. A method for controlling the movement of an Abrikosov vortex of an element composed of a superconducting material, referred to as a superconductor, comprising a step of non-uniform heating, in a heating zone, of the superconductor having the Abrikosov vortex in such a way as to move the Abrikosov vortex towards the heating zone.

2. The control method according to claim 1, wherein, during the step of non-uniform heating of the superconductor, the heating zone is heated by applying a laser beam.

3. The control method according to claim 2, comprising a step of focusing the laser beam on the heating zone.

4. The control method according to claim 2, wherein, during the heating step, the laser beam generates an attraction force on the vortex of value:
f_T=−Φ_0/4π*(∂H_c1)/∂T*|∇T|, where Φ_0 is a magnetic flux quantum, H_c1 is a first critical field of the superconductor, and T is a temperature associated with the laser beam.

5. The control method according to claim 4, wherein the Abrikosov vortex moves towards the heating zone if the attraction force generated by the laser beam is greater than the force trapping the Abrikosov vortex in the superconductor.

6. The control method according to claim 5, wherein the trapping force is equal to:
F_p= [symbol] j_c Φ [symbol] _0, where Φ_0 is a magnetic flux quantum and j_c is a critical current of the superconductor.

7. The control method according to claim 2, wherein the laser power is between 1 μW and 1000 μW.

8. The control method according to claim 2, wherein the wavelength of the laser is within the visible electromagnetic spectrum.

9. The control method according to claim 5, comprising a step of determining the value of the trapping force by means of the minimum force to be applied by the laser beam such that the Abrikosov vortex is moved.

10. Use of the control method according to claim 1 to form a distribution of vortices in a superconductor, wherein the method according to any preceding claim is applied to at least one of the vortices of an initial distribution of vortices.

11. The use according to claim 10, wherein a method for controlling the movement of an Abrikosov vortex of an element composed of a superconducting material, referred to as a superconductor, comprising a step of non-uniform heating, in a heating zone, of the superconductor having the Abrikosov vortex in such a way as to move the Abrikosov vortex towards the heating zone is successively applied to each Vortex of the distribution of vortices.

12. The use according to claim 10, comprising a step for avoiding collisions between the vortex moved by a method for controlling the movement of an Abrikosov vortex of an element composed of a superconducting material, referred to as a superconductor, comprising a step of non-uniform heating, in a heating zone, of the superconductor having the Abrikosov vortex in such a way as to move the Abrikosov vortex towards the heating zone.

13. The use of the control method according to claim 1 in a Josephson junction provided with an Abrikosov vortex, for controlling a value of a critical current of said Josephson junction.

14. The use of the control method according to claim 1 for storing information, wherein information is written by the movement of the Abrikosov vortex.

15. A computer program comprising a set of instructions implementing the steps of the method according to claim 1 when executed by a processor.

16. A non-transitory computer-readable storage medium comprising a computer program according to the preceding claim.
